(19) United States
(12) Patent Application Publication
(10) Pub. No.: US 2025/0241111 A1
(43) Pub. Date: Jul. 24, 2025

(54) LIGHT EMITTING DEVICE, DISPLAY DEVICE, PHOTOELECTRIC CONVERSION DEVICE, ELECTRONIC APPARATUS, AND WEARABLE DEVICE

(71) Applicant: CANON KABUSHIKI KAISHA, Tokyo (JP)

(72) Inventor: HIDEMASA OSHIGE, Kanagawa (JP)

(21) Appl. No.: 18/975,421

(22) Filed: Dec. 10, 2024

(30) Foreign Application Priority Data
Jan. 18, 2024 (JP) 2024-006211

(51) Int. Cl. H10K 39/34; G06F 3/01; H04N 23/63

(52) U.S. Cl. CPC H10K 39/34; G06F 3/013; H04N 23/63

(57) ABSTRACT

A light emitting device is provided. The device includes a display substrate having a main surface that includes a display region where a display element is arranged and a peripheral region where an infrared ray emitting element and an infrared ray receiving element are arranged, and a light-transmissive substrate arranged to cover the main surface. In an orthogonal projection to the main surface, the light-transmissive substrate includes a first region that overlaps the display region and a second region that overlaps the peripheral region, and in each of overlap regions in the second region that overlap the infrared ray emitting element and the infrared ray receiving element in the orthogonal projection to the main surface, a concave portion thinner than the first region or an opening portion is provided.

### BACKGROUND OF THE INVENTION

### Field of the Invention

The present invention relates to a light emitting device, a display device, a photoelectric conversion device, an electronic apparatus, and a wearable device.

### Description of the Related Art

A light emitting device that includes a light emitting layer including an organic compound layer is sometimes used in the viewfinder of a camera, a head mounted display, a wearable device called smartglasses, and the like. Such a light emitting device can detect the line of sight of a user and reflect the detected line-of-sight information on driving of the light emitting device. Japanese Patent Laid-Open No. 2021-015731 describes a light emitting device where an infrared light emitting element that emits infrared light and a light receiving element for detecting reflected light from the eyeball of the user are arranged on a display substrate where an organic EL light emitting element is provided.

### SUMMARY OF THE INVENTION

Japanese Patent Laid-Open No. 2021-015731 describes that a facing substrate for protecting the display substrate is arranged to cover the infrared light emitting element and the light receiving element. The light emitting from the infrared light emitting element and the reflected light from the eyeball of the user are partially absorbed by passing through the facing substrate, and this can cause a decrease in infrared light receiving sensitivity.

Some embodiments of the present invention provide a technique advantageous in suppressing a decrease in infrared light receiving sensitivity.

According to some embodiments, a light emitting device comprising a display substrate having a main surface that includes a display region where a display element is arranged and a peripheral region where an infrared ray emitting element and an infrared ray receiving element are arranged, and a light-transmissive substrate arranged to cover the main surface, wherein in an orthogonal projection to the main surface, the light-transmissive substrate includes a first region that overlaps the display region and a second region that overlaps the peripheral region, and in each of overlap regions in the second region that overlap the infrared ray emitting element and the infrared ray receiving element in the orthogonal projection to the main surface, a concave portion thinner than the first region or an opening portion is provided, is provided.

According to some other embodiments, a light emitting device comprising a display substrate having a main surface that includes a display region where a display element is arranged and a peripheral region where an infrared ray emitting element and an infrared ray receiving element are arranged, and a light-transmissive substrate arranged to cover the main surface, wherein in an orthogonal projection to the main surface, the light-transmissive substrate covers the display region and does not cover a region of the peripheral region where the infrared ray emitting element and the infrared ray receiving element are arranged, is provided.

Further features of the present invention will become apparent from the following description of exemplary embodiments (with reference to the attached drawings).

### BRIEF DESCRIPTION OF THE DRAWINGS

FIG. 1 is a view showing an example of the arrangement of a light emitting device and a line-of-sight detection operation according to an embodiment;

FIG. 2 is a view showing an example of the arrangement of the light emitting device shown in FIG. 1;

FIG. 3 is a view showing an example of the arrangement of the light emitting device shown in FIG. 1;

FIG. 4 is a view showing an example of the arrangement of the light emitting device shown in FIG. 1;

FIGS. 5A and 5B are sectional views showing an example of the arrangement of the pixel of the light emitting device shown in FIG. 1;

FIGS. 6A to 6C are views showing an example of an image forming device using the light emitting device according to the embodiment;

FIG. 7 is a view showing an example of a display device using the light emitting device according to the embodiment;

FIG. 8 is a view showing an example of a photoelectric conversion device using the light emitting device according to the embodiment;

FIG. 9 is a view showing an example of an electronic apparatus using the light emitting device according to the embodiment;

FIGS. 10A and 10B are views each showing an example of a display device using the light emitting device according to the embodiment;

FIG. 11 is a view showing an example of an illumination device using the light emitting device according to the embodiment;

FIG. 12 is a view showing an example of a moving body using the light emitting device according to the embodiment; and

FIGS. 13A and 13B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

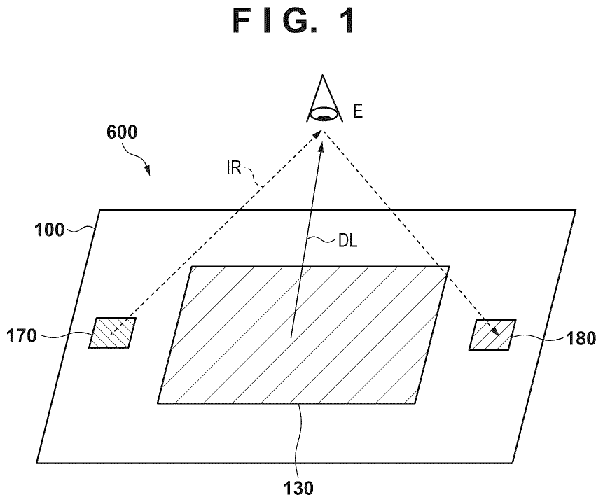

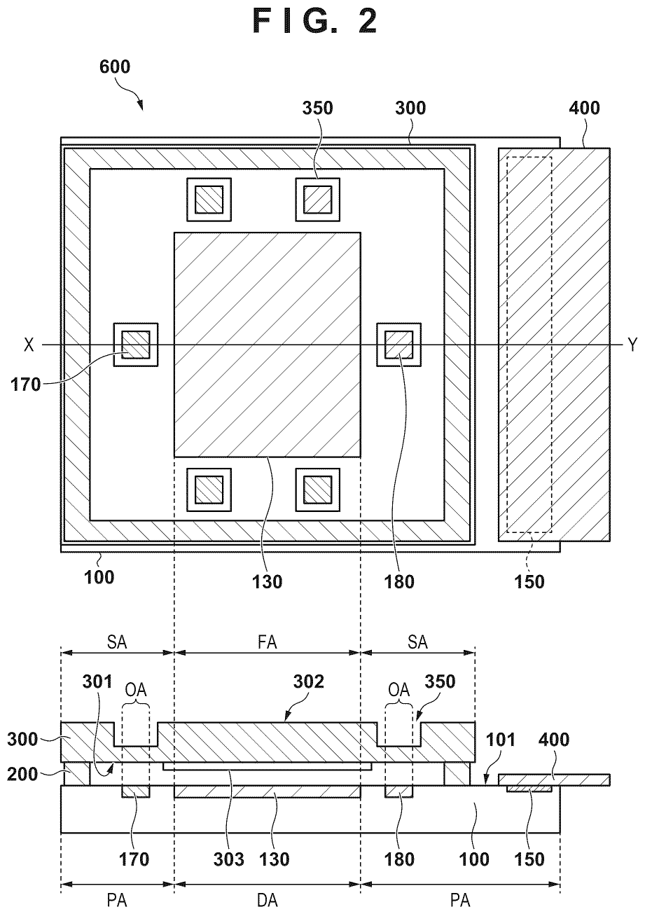

With reference to FIGS. 1 to 4, a light emitting device according to an embodiment of the present disclosure will be described. FIG. 1 is a view schematically showing an example of the arrangement of a light emitting device 600 and a line-of-sight detection operation according to the present disclosure. The light emitting device 600 includes a display substrate 100 where a display element 130, an infrared ray emitting element 170, and an infrared ray receiving element 180 are arranged on a main surface 101 (shown from FIG. 2). The display element 130 displays an image or the like by emitting display light DL. The infrared ray emitting element 170 emits infrared light IR to an eyeball E of the observer who is gazing at the image or the like displayed on the display element 130. The infrared ray receiving element 180 detects reflected light of the infrared light IR emitted from the infrared ray emitting element 170, thereby obtaining a captured image of the eyeball E. The line of sight of the observer to the displayed image is detected from the captured image of the eyeball E obtained by the capturing operation using the infrared light IR. An arbitrary known method can be applied to the line-of-sight detection using the captured image of the eyeball E. As an example, a line-of-sight detection method based on a Purkinje image obtained by reflection of irradiation light by a cornea can be used. More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball E, thereby detecting the line-of-sight of the user.

With reference to FIG. 2, the light emitting device 600 according to this embodiment will be described in more detail. A plan view showing an example of the arrangement of the light emitting device 600 in this embodiment is shown on the upper side of FIG. 2, and a sectional view taken along a line X-Y in the plan view is shown on the lower side.

The light emitting device 600 includes the display substrate 100 having the main surface 101 that includes a display region DA where the display element 130 is arranged and a peripheral region PA where the infrared ray emitting element 170 and the infrared ray receiving element 180 are arranged, and a light-transmissive substrate 300 arranged to cover the main surface 101 of the display substrate 100. Further, an external connection terminal 150 and the like can be arranged in the main surface 101 of the display substrate 100. For example, a circuit board 400 such as a flexible printed board can be bonded to the terminal 150 via a bonding member (not shown). The display substrate 100 and the light-transmissive substrate 300 are adhered via an adhesive member 200 configured to connect the display substrate 100 and the light-transmissive substrate 300 such that the main surface 101 of the display substrate 100 and a main surface 301 of the light-transmissive substrate 300 face each other. As shown in FIG. 2, in an orthogonal projection to the main surface 101 of the display substrate 100, the infrared ray emitting element 170 and the infrared ray receiving element 180 are arranged between the display element 130 and the adhesive member 200.

The display substrate 100 includes the display region DA and the peripheral region PA as described above. The display element 130 and semiconductor elements (not shown) such as a transistor for driving the display element 130 are provided in the display region DA. A driving circuit (not shown) for operating the display element 130 arranged in the display region DA, and a processing circuit such as a digital-analog conversion circuit (DAC) that processes a luminance signal input to the display element 130 are provided in the peripheral region PA. The infrared ray emitting element 170, the infrared ray receiving element 180, the terminal 150, and the adhesive member 200 described above can also be arranged in the peripheral region PA. A sealing layer for protecting the display element 130 against an external damage, moisture, oxygen, and the like may be provided on the display element 130.

The light-transmissive substrate 300 includes a region FA that overlaps the display region DA and a region SA that overlaps the peripheral region PA in the orthogonal projection to the main surface 101 of the display substrate 100. Further, in each of overlap regions OA in the region SA of the light-transmissive substrate 300 that overlap the infrared ray emitting element 170 and the infrared ray receiving element 180 in the orthogonal projection to the main surface 101 of the display substrate 100, a concave portion thinner than the region FA or an opening portion is provided. In the arrangement shown in FIG. 2, a concave portion 350 is provided in each overlap region OA of the light-transmissive substrate 300.

For the light-transmissive substrate 300, a light-transmissive inorganic material such as glass or quartz or a light-transmissive plastic material such as an acrylic resin is used. The concave portion 350 provided in the light-transmissive substrate 300 is recessed, in the thickness direction of the light-transmissive substrate 300, from a main surface 302 of the light-transmissive substrate 300 on the opposite side of the main surface 301 facing the display substrate 100. The thickness of the light-transmissive substrate 300 in the concave portion 350 provided in the light-transmissive substrate 300 is thinner than in the region other than the concave portion 350, for example, in the region FA overlapping the display region DA. As the thickness of the light-transmissive substrate 300 in the concave portion 350 decreases, the transmission amount of infrared light (infrared rays) increases and the deterioration of the line-of-sight detection function can be suppressed. Hence, for example, the thickness of the light-transmissive substrate 300 in the concave portion 350 may be half or less the thickness of the region FA. On the other hand, if the thickness of the light-transmissive substrate 300 in the concave portion 350 is excessively small, the light-transmissive substrate 300 in the concave portion 350 may be damaged due to the internal pressure fluctuation in the sealed space surrounded by the adhesive member 200. Accordingly, for example, the thickness of the light-transmissive substrate 300 in the concave portion 350 may be 0.1 mm or more. For example, if the thickness of the light-transmissive substrate 300 in the region FA and the like other than the concave portion 350 is 0.8 mm, the thickness of the light-transmissive substrate 300 in the concave portion 350 may be between 0.1 mm (inclusive) and 0.4 mm (inclusive).

Here, as shown in FIG. 2, in the orthogonal projection to the main surface 101 of the display substrate 100, the concave portion 350 provided in, among the overlap regions OA, the overlap region OA overlapping the infrared ray emitting element 170 may be larger than the infrared ray emitting element 170. Similarly, in the orthogonal projection to the main surface 101 of the display substrate 100, the concave portion 350 provided in, among the overlap regions OA, the overlap region OA overlapping the infrared ray receiving element 180 may be larger than the infrared ray receiving element 180. With this, as shown in FIG. 1, it is possible to suppress that a light beam inclined from the normal direction of the main surface 101 of the display substrate 100 passes through the light-transmissive substrate 300 other than in the concave portion 350. Note that in the arrangement shown in the sectional view of FIG. 2, the concave portion 350 is provided in the main surface 302 of the light-transmissive substrate 300, but it may be provided in the main surface 301.

In the arrangement shown in FIG. 2, the display region DA has an almost rectangular shape. The diagonal length of the display region DA may be, for example, 5 mm to 50 mm. As shown in FIG. 2, the infrared ray emitting element 170 may be arranged in each of five regions along three sides of the outer periphery of the display region DA, and the infrared ray receiving element 180 may be arranged along one side of the outer periphery of the display region DA where no infrared ray emitting element 170 is arranged. Even if the infrared ray emitting element 170 is arranged in one region, the line-of-sight detection function can be provided. On the other hand, as the number of regions where the infrared ray emitting element 170 is arranged increases, the total intensity of infrared light increases, and the eyeball E of the observer can be irradiated with infrared light from various angles. Therefore, for example, it is possible to suppress that the infrared light is blocked by the eyelashes of the observer so that the line-of-sight detection function deteriorates.

For the adhesive member 200, for example, an ultraviolet-curable or thermosetting acrylic resin or epoxy resin can be used. In the orthogonal projection to the main surface 101 of the display substrate 100, the adhesive member 200 is arranged so as not to overlap the infrared ray emitting element 170 and the infrared ray receiving element 180. With this arrangement, a loss of infrared light as the infrared light is transmitted through the adhesive member 200 can be suppressed. More specifically, if the adhesive member 200 includes a spacer for keeping a certain distance between the display substrate 100 and the light-transmissive substrate 300 or an inorganic filler for any other desired purpose, the spacer or inorganic filler may hinder transmission of infrared light. Therefore, the adhesive member 200 may be arranged so as not to cover the infrared ray emitting element 170 and the infrared ray receiving element 180.

As shown in FIG. 2, various kinds of optical films 303 such as a wave plate and a polarizing plate may be arranged on the main surface 301 of the light-transmissive substrate 300. The optical film 303 may be arranged on the main surface 302 of the light-transmissive substrate 300. In that case, the optical film 303 can be arranged so as not to cover the concave portion 350. With this arrangement, a loss of infrared light caused by the optical film 303 can be suppressed.

As has been described above, in this embodiment, the concave portion 350 is provided in the light-transmissive substrate 300 in each of the overlap regions OA overlapping the infrared ray emitting element 170 and the infrared ray receiving element 180. This can reduce a loss of infrared light as the infrared light passes through the light-transmissive substrate 300. As a result, it is possible to suppress a decrease in the light receiving sensitivity with respect to infrared light for line-of-sight detection, and the deterioration of the line-of-sight detection function can be suppressed.

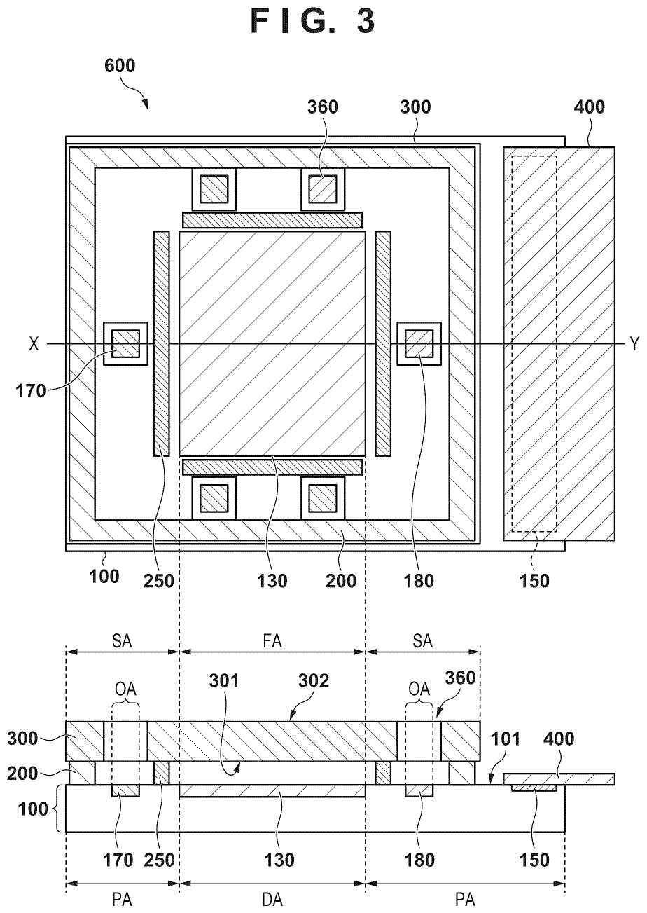

FIG. 3 is a view showing a modification of the light emitting device 600 shown in FIG. 2. In the light emitting device 600 shown in FIG. 3, as compared to the arrangement shown in FIG. 2, an opening portion 360 extending from the main surface 301 of the light-transmissive substrate 300 to the main surface 302 is provided in the light-transmissive substrate 300 instead of the concave portion 350. In addition, a resin member 250 is arranged in the light emitting device 600 shown in FIG. 3. The remaining arrangement may be similar to the arrangement shown in FIG. 2, so that differences will be mainly described.

In the arrangement shown in FIG. 3, in the region SA of the light-transmissive substrate 300 overlapping the peripheral region PA, the opening portion 360 is provided in each of the overlap regions OA that overlap the infrared ray emitting element 170 and the infrared ray receiving element 180 in the orthogonal projection to the main surface 101 of the display substrate 100. Since the light-transmissive substrate 300 has an opening on each of the infrared ray emitting element 170 and the infrared ray receiving element 180, a loss of infrared light due to the light-transmissive substrate 300 does not occur. Hence, as compared to the arrangement shown in FIG. 2, a decrease in the light receiving sensitivity with respect to infrared light for line-of-sight detection can be further suppressed.

Here, as in the arrangement shown in FIG. 2, in the orthogonal projection to the main surface 101 of the display substrate 100, the opening portion 360 provided in, among the overlap regions OA, the overlap region OA overlapping the infrared ray emitting element 170 may be larger than the infrared ray emitting element 170. Similarly, in the orthogonal projection to the main surface 101 of the display substrate 100, the opening portion 360 provided in, among the overlap regions OA, the overlap region OA overlapping the infrared ray receiving element 180 may be larger than the infrared ray receiving element 180. With this, as shown in FIG. 1, it is possible to suppress that infrared light inclined from the normal direction of the main surface 101 of the display substrate 100 enters the light-transmissive substrate 300.

On the other hand, if a foreign substance enters from the outside through the opening portion 360 provided in the light-transmissive substrate 300 and adheres to the display region DA, the display quality of the light emitting device 600 may be impaired. To prevent this, in this embodiment, in the orthogonal projection to the main surface 101 of the display substrate 100, the resin member 250 is arranged between the opening portion 360 and the display region DA (display element 130) and between the display substrate 100 and the light-transmissive substrate 300. This can suppress that a foreign substance entering from the opening portion 360 enters the display region DA.

For the resin member 250, an arbitrary resin such as an acrylic resin or an epoxy resin can be used. For example, the resin member 250 may be formed using the same material as the adhesive member 200. In this case, the adhesive member 200 and the resin member 250 can be formed in the same step, and this can suppress an increase in the number of manufacturing steps for manufacturing the light emitting device 600.

In the orthogonal projection to the main surface 101 of the display substrate 100, the resin member 250 is arranged so as not to overlap the infrared ray emitting element 170 and the infrared ray receiving element 180. With this arrangement, a loss of infrared light as the infrared light is transmitted through the resin member 250 can be suppressed. In this case, the resin member 250 may include a resin added with particles of aluminum oxide or the like that has a high reflectance in the near infrared region. With this, the efficiency of reflecting the infrared light, of the infrared light emitted from the infrared ray emitting element 170, significantly inclined from the normal direction of the main surface 101 of the display substrate 100 on the resin member 250 and extracting it in the normal direction of the main surface 101 of the display substrate 100 improves.

Alternatively, for example, the resin member 250 may be formed of a material having a high transmittance with respect to infrared light, such as a light-transmissive resin. In this case, an infrared ray reflective layer (not shown) for reflecting infrared rays may be arranged on, of the surfaces of the resin member 250, at least a surface facing the opening portion 360 in the orthogonal projection to the main surface 101 of the display substrate 100. With this, the infrared light emitted from the infrared ray emitting element 170 can be efficiently extracted in the normal direction of the main surface 101 of the display substrate 100. As the infrared ray reflective layer, for example, a metal layer using aluminum, silver, or the like, or a layer containing white particles of aluminum oxide or the like that exhibits a high reflectance in the near infrared region as described above can be used. If the infrared ray reflective layer is a metal layer, the film thickness may be about 0.3 μm to 1 μm, and it can be formed using, for example, a sputtering method. A similar infrared ray reflective layer may also be arranged on the inner wall of the opening portion 360 of the light-transmissive substrate 300. With this, the infrared light emitted from the infrared ray emitting element 170 can be further efficiently extracted in the normal direction of the main surface 101 of the display substrate 100.

A gap (not shown) may be provided between the resin member 250 and the light-transmissive substrate 300. In other words, at least a part of the resin member 250 may not be in contact with the light-transmissive substrate 300. When the gap is provided, if heat is applied to the light emitting device 600, it can be suppressed that a stress is generated due to the difference in the thermal expansion coefficient between the light-transmissive substrate 300 and the display substrate 100 and this damages the resin member 250. However, if the gap is large, a foreign substance easily enters the display region DA. Even if a foreign substance equal to or smaller than the size of a pixel arranged in the display element 130 adheres to the display region DA, this does not significantly affect the display quality. Therefore, the size of the gap may be equal to or smaller than the size of a pixel arranged in the display element 130. The gap may be, for example, of 10 μm or less.

The plan view of FIG. 3 shows an example in which the resin member 250 is formed along each of four sides of the outer periphery of the display region

DA. In the orthogonal projection to the main surface 101 of the display substrate 100, the resin member 250 may continuously or intermittently surround the display region DA. If the resin member 250 is formed using, for example, a light-transmissive resin, the resin member 250 may be formed to cover the entire display region DA. Even in that case, by forming the resin member 250 so as not to cover the infrared ray emitting element 170 and the infrared ray receiving element 180, a loss of infrared light can be suppressed.

In the arrangement shown in FIG. 3, various kinds of optical films 303 may also be arranged on at least one of the main surface 301 and the main surface 302 of the light-transmissive substrate 300 as shown in FIG. 2. In that case, the optical film 303 can be arranged so as not to cover the opening portion 360. With this arrangement, a loss of infrared light caused by the optical film 303 can be suppressed.

As has been described above, in this embodiment, the opening portion 360 is provided in the light-transmissive substrate 300 in each of the overlap regions OA overlapping the infrared ray emitting element 170 and the infrared ray receiving element 180. This can reduce a loss of infrared light as compared to the arrangement shown in FIG. 2 where the concave portion 350 is arranged. As a result, it is possible to suppress a decrease in the light receiving sensitivity with respect to infrared light for line-of-sight detection, and the deterioration of the line-of-sight detection function can be suppressed.

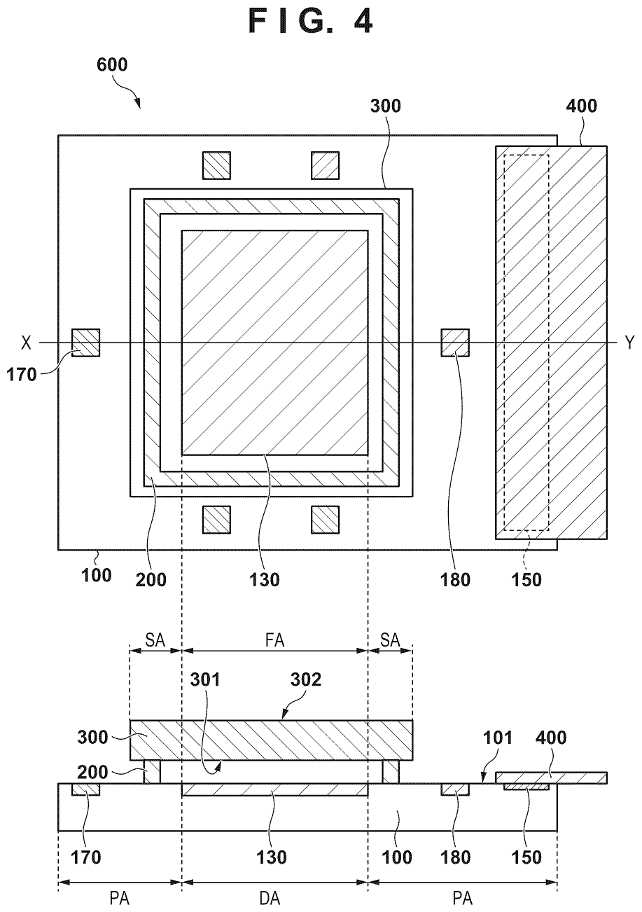

FIG. 4 is a view showing a modification of the light emitting device 600 shown in FIG. 2 or 3. As compared to the arrangements shown in FIGS. 2 and 3, in the light emitting device 600 shown in FIG. 4, in the orthogonal projection to the main surface 101 of the display substrate 100, the light-transmissive substrate 300 covers the display region DA (display element 130) and does not cover the region of the peripheral region PA where the infrared ray emitting element 170 and the infrared ray receiving element 180 are arranged. More specifically, in the orthogonal projection to the main surface 101 of the display substrate 100, the outer edge of the light-transmissive substrate 300 is arranged between the display region DA (display element 130) and the infrared ray emitting element 170 and between the display region DA (display element 130) and the infrared ray receiving element 180. The remaining arrangement may be similar to those shown in FIGS. 2 and 3, so that differences will be mainly described.

In the light emitting device 600 shown in FIG. 4, the adhesive member 200 is arranged along the outer periphery of the display region DA to adhere the display substrate 100 and the light-transmissive substrate 300. The light-transmissive substrate 300 does not cover the infrared ray emitting element 170 and the infrared ray receiving element 180. Accordingly, in the orthogonal projection to the main surface 101 of the display substrate 100, the adhesive member 200 is arranged between the display region DA (display element 130) and the infrared ray emitting element 170 and between the display region DA (display element 130) and the infrared ray receiving element 180. As a result, the outer edge of the light-transmissive substrate 300 is arranged between the outer edge of the adhesive member 200 and a region of the peripheral region PA where the infrared ray emitting element 170 and the infrared ray receiving element 180 are arranged.

In the arrangement shown in FIG. 4, an infrared ray reflective layer (not shown) may be arranged on the side surface located in the outer edge of at least one of the light-transmissive substrate 300 and the adhesive member 200. The infrared ray reflective layer can have an arrangement similar to that of the infrared ray reflective layer described above. For example, the adhesive member 200 may include a resin added with particles of aluminum oxide or the like that exhibits a high reflectance in the near infrared region. With this, the component of the infrared light emitted from the infrared ray emitting element 170 and traveling toward the light-transmissive substrate 300 and the adhesive member 200 can be efficiently extracted in the normal direction of the main surface 101 of the display substrate 100.

As has been described above, in this embodiment, the light-transmissive substrate 300 is not arranged in the region overlapping the infrared ray emitting element 170 and the infrared ray receiving element 180. Therefore, a loss of infrared light caused by the light-transmissive substrate 300 is almost eliminated. As a result, it is possible to suppress a decrease in the light receiving sensitivity with respect to infrared light for line-of-sight detection, and the deterioration of the line-of-sight detection function can be suppressed.

Next, a manufacturing method of the light emitting device 600 will be described. Here, as an example, a manufacturing method in a case where each pixel arranged in the display element 130 includes a light emitting element such as an organic electroluminescence (EL) element and the light emitting device 600 is a so-called organic EL light emitting device will be described.

The display substrate 100 may be a semiconductor substrate made of single-crystal silicon or the like. A semiconductor element is formed on the display substrate 100. The semiconductor element is, for example, a transistor or a diode, and at least a part thereof may be arranged in the display substrate. An insulating layer is provided on the semiconductor element. The insulating layer can include silicon oxide, silicon nitride, silicon carbide, or the like. However, the material used for the insulating layer is not limited to this, and a suitable dielectric material may be used. Silicon oxynitride may be considered as a type of silicon oxide since it contains oxygen and silicon as main elements. Each of silicon oxynitride and silicon carbonitride may be considered as a type of silicon nitride since they contain nitrogen and silicon as main elements.

The terminal 150 and a wiring layer including a wiring pattern using a conductive material such as aluminum or copper and extending along the main surface 101 of the display substrate 100 are arranged in the insulating layer. The wiring layer including the wiring pattern may include one layer, or two or more layers. A plug electrically connecting the wiring pattern and the semiconductor element or the terminal 150 is arranged in the insulating layer. If a plurality of wiring layers each including a wiring pattern are provided, the plug may electrically connect the wiring patterns arranged in the respective wiring layers. The terminal 150 may be formed simultaneously with formation of the wiring pattern. It can also be said that the terminal 150 and at least a part of the wiring pattern are arranged in the same wiring layer.

The display element 130 is arranged in the display region DA of the display substrate 100. For example, the display element 130 is integrally shown in FIG. 1. However, a plurality of pixels each including an organic EL light emitting element are arranged, and each pixel emits light with an arbitrary luminance. The display element 130 is electrically connected to the semiconductor element. The organic EL light emitting element can include a lower electrode, an organic compound layer including the light emitting layer, and an upper electrode in this order. The organic EL light emitting element may emit light of any color, and may emit white light. Light emission colors may be different between pixels. A sealing layer for suppressing permeation of moisture, oxygen, and the like is formed on the display element 130, and a color filter layer, a lens structure, or the like can be provided on the sealing layer, as appropriate.

The infrared ray emitting element 170 is formed in each of a plurality of regions in the peripheral region PA of the display substrate 100. The infrared ray emitting element 170 is integrally shown in FIG. 1, but one infrared ray emitting element 170 may be formed from a plurality of light emitting elements, and each of them may emit light with an arbitrary luminance. The infrared ray emitting element 170 is not particularly limited as long as it includes an infrared light emitting element that can emit infrared light, and may include, for example, an organic light emitting element or an LED element. If the infrared ray emitting element 170 is an organic light emitting element, the organic light emitting element arranged in the display element 130 and the infrared ray emitting element 170 can be manufactured by the same process, and this can suppress the number of manufacturing steps. If the infrared ray emitting element 170 is an organic light emitting element, it can include a lower electrode, an organic compound layer including a light emitting layer, and an upper electrode in this order, like the display element 130.

A plurality of the infrared ray receiving elements 180 are formed in the peripheral region PA of the display substrate 100. The infrared ray receiving element 180 is integrally shown in FIG. 1, but one infrared ray receiving element 180 may be formed from a plurality of light receiving elements. The infrared ray receiving element 180 only requires to include a photoelectric conversion element which is sensitive in the infrared region. For the infrared ray receiving element 180, for example, a photodiode, an organic photoelectric conversion element, an inorganic photoelectric conversion element, or the like can be used.

For the light-transmissive substrate 300, an inorganic material such as glass or quartz, or an organic material such as a plastic like an acrylic plate is used. If the light-transmissive substrate 300 is made of glass or quartz, the concave portion 350 and the opening portion 360 can be formed by etching. If the light-transmissive substrate 300 is made of a plastic, the concave portion 350 and the opening portion 360 may be formed by cutting. Alternatively, the light-transmissive substrate 300 including the concave portion 350 or the opening portion 360 may be directly formed by molding.

The light-transmissive substrate 300 formed with the concave portion 350 or the opening portion 360 in advance is adhered to the display substrate 100 via the adhesive member 200. An ultraviolet-curable acrylic resin or epoxy resin can be used for the adhesive member 200. The circuit board 400 is electrically connected onto the terminal 150 via a connection member. The circuit board 400 may be a wiring board such as a rigid substrate or a flexible substrate, or a driving circuit chip for operating the display element 130. For example, the circuit board 400 is a flexible wiring board such as a glass epoxy substrate or polyimide film where the wiring patterns are provided. For the bonding member, an anisotropic conductive film (ACF) or the like can be used. The ACF contains conductive particles. When the conductive particles are sandwiched and compression-bonded between the terminal 150 of the display substrate 100 and the electrode of the circuit board 400, the terminal 150 of the display substrate 100 and the electrode of the circuit board 400 are electrically connected. When the display substrate 100 is connected to an external power supply or control device via the circuit board 400, the light emitting device 600 can operate. By including the above steps, the light emitting device 600 functioning as the light emitting device according to this embodiment is manufactured.

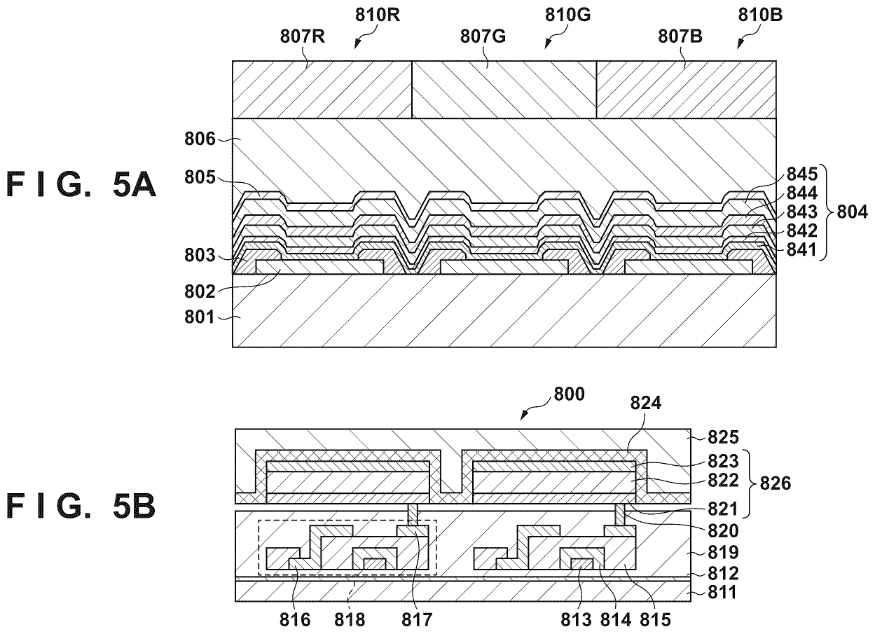

Here, application examples in which the light emitting device 600 according to this embodiment is applied to an image forming device, a display device, a photoelectric conversion device, an electronic apparatus, an illumination device, a moving body, and a wearable device will be described with reference to FIGS. 5A to 13B. The description will be given assuming that, for example, an organic light emitting element such as an organic EL element using an organic light emitting material is arranged in the pixel arranged in the display element 130 of the display substrate 100 of the light emitting device 600. Details of each component arranged in the pixel arranged in the display element 130 of the display substrate 100 of the light emitting device 600 described above will be described first, and the application examples will be described after that.

### Arrangement of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in an arrangement including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this arrangement, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 5A shows an example of the pixel arranged in the display element 130 of the display substrate 100 of the light emitting device 600. The pixel includes sub-pixels 810 (pixels). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

A display device 800 (corresponding to the above-described light emitting device 600) shown in FIG. 5B is provided with an organic light emitting element 826 and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 5B. That is, one of the anode and cathode and one of the source electrode and drain electrode of the TFT are electrically connected. The TFT indicates a thin-film transistor.

In the display device 800 shown in FIG. 5B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 5B but may be used as another switching element.

The transistor used in the display device 800 shown in FIG. 5B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 5B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

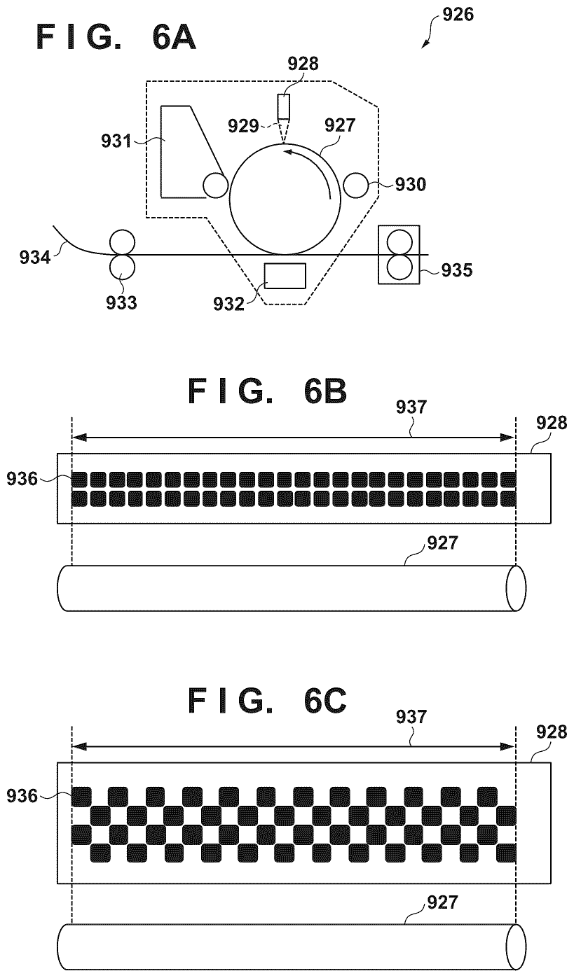

FIGS. 6A to 6C are schematic views showing an example of an image forming device using the light emitting device 600 according to this embodiment. An image forming device 926 shown in FIG. 6A includes a photosensitive member 927, an exposure light source 928, a developing unit 931, a charging unit 930, a transfer device 932, a conveyance unit 933 (a conveyance roller in the arrangement shown in FIG. 6A), and a fixing device 935.

Light 929 is emitted from the exposure light source 928, and an electrostatic latent image is formed on the surface of the photosensitive member 927. The light emitting device 600 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 6B and 6C is a schematic view showing a form in which a plurality of light emitting units 936 are arranged in the exposure light source 928 along the longitudinal direction of a long substrate. The light emitting device 600 can be applied to each of the light emitting units 936. That is, a plurality of the pixels are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 6B shows a form in which the light emitting units 936 are arranged along the long-axis direction of the photosensitive member 927. FIG. 6C shows a form, which is a modification of the arrangement of the light emitting units 936 shown in FIG. 6B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 6C can be referred to as, for example, an arrangement in a grid pattern, an arrangement in a staggered pattern, or an arrangement in a checkered pattern.

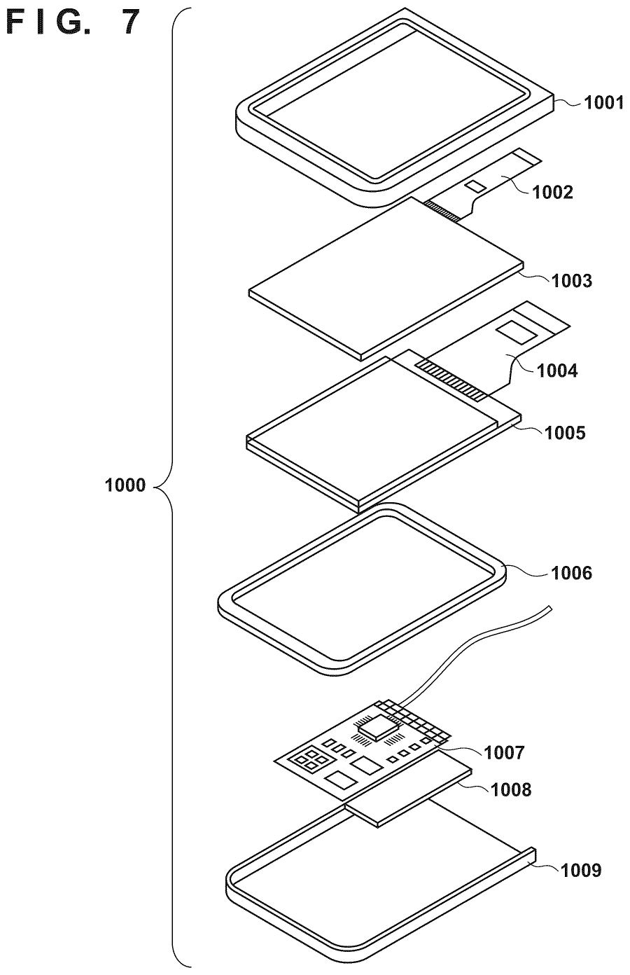

FIG. 7 is a schematic view showing an example of the display device using the light emitting device 600 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 600 can be applied to the display panel 1005. The pixels arranged in the light emitting device 600 functioning as the display panel 1005 operate in a state in which they are connected to the active elements such as transistors arranged on the circuit board 1007.

The display device 1000 shown in FIG. 7 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

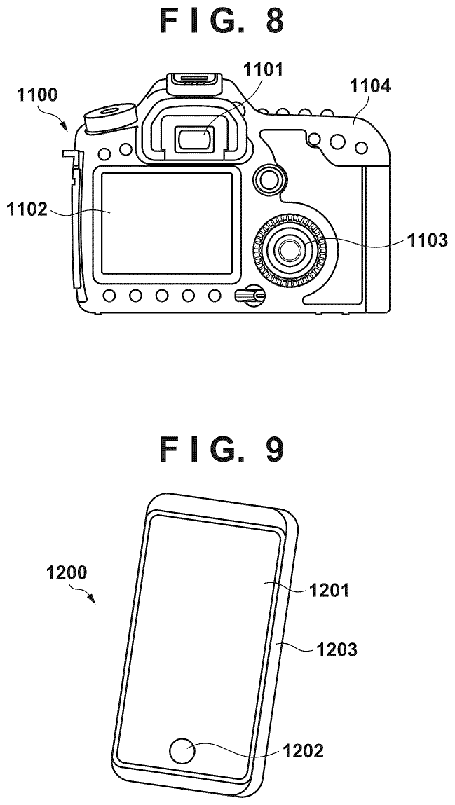

FIG. 8 is a schematic view showing an example of the photoelectric conversion device using the light emitting device 600 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 600 according to this embodiment can be applied to the viewfinder 1101 or the rear display 1102 as a display unit. In this case, the light emitting device 600 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting device 600 in which the pixel including the light emitting element using the organic light emitting material such as an organic EL element is arranged may be used for the viewfinder 1101 or the rear display 1102. This is so because the organic light emitting material has a high response speed. The light emitting device 600 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 600 may be applied to a display unit of an electronic apparatus. At this time, the display unit can have both a display function and an operation function. Examples of the portable terminal are a portable phone such as a smartphone, a tablet, and a head mounted display.

FIG. 9 is a schematic view showing an example of an electronic apparatus using the light emitting device 600 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 600 according to this embodiment can be applied to the display unit 1201.

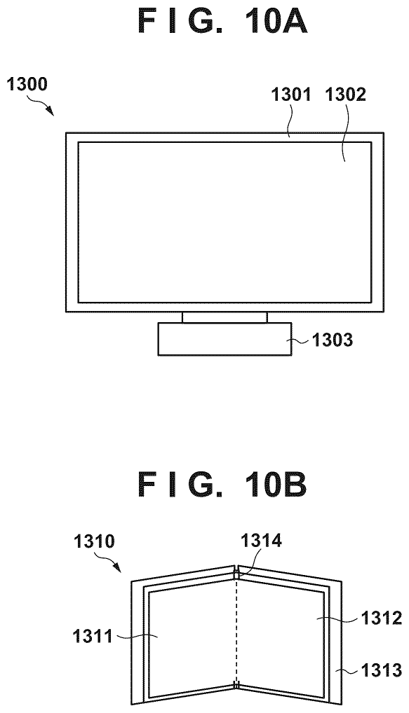

FIGS. 10A and 10B are schematic views showing examples of the display device using the light emitting device 600 according to this embodiment. FIG. 10A shows a display device such as a television monitor or a PC monitor. A display device 1300 includes a frame 1301 and a display unit 1302. The light emitting device 600 according to this embodiment can be applied to the display unit 1302. The display device 1300 can include a base 1303 that supports the frame 1301 and the display unit 1302. The base 1303 is not limited to the form shown in FIG. 10A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 10B is a schematic view showing another example of the display device using the light emitting device 600 according to this embodiment. A display device 1310 shown in FIG. 10B can be folded, and is a so-called foldable display device. The display device 1310 includes a first display unit 1311, a second display unit 1312, a housing 1313, and a bending point 1314. The light emitting device 600 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

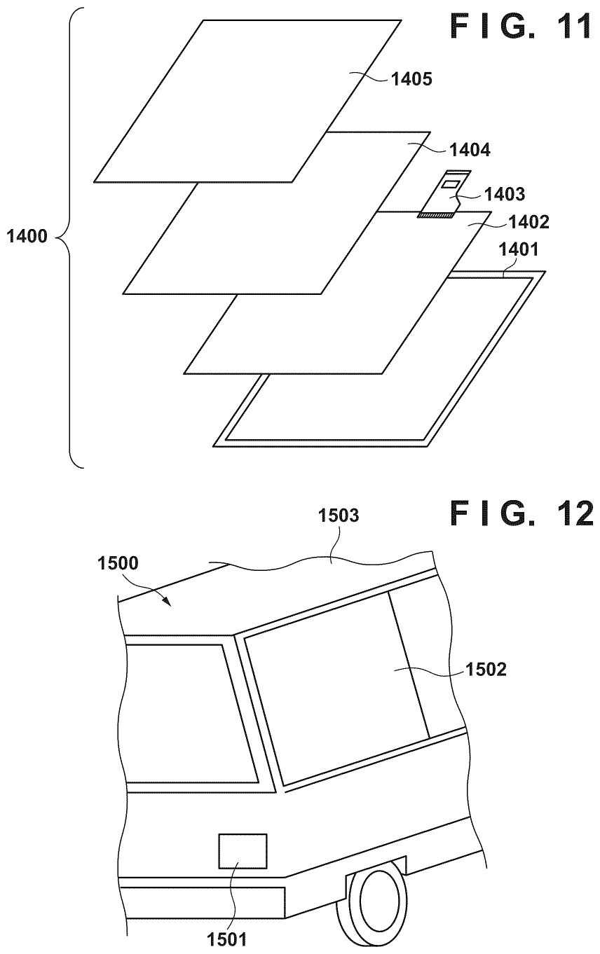

FIG. 11 is a schematic view showing an example of the illumination device using the light emitting device 600 according to this embodiment. An illumination device 1400 can include a housing 1401, a light source 1402, a circuit board 1403, an optical film 1404, and a light diffusing unit 1405. The light emitting device 600 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 600 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 12 is a schematic view of an automobile having a taillight as an example of a vehicle lighting appliance using the light emitting device 600 according to this embodiment. An automobile 1500 has a taillight 1501, and can have a form in which the taillight 1501 is turned on when performing a braking operation or the like. The light emitting device 600 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 600 according to this embodiment can be applied to the taillight 1501. The taillight 1501 can include a protection member for protecting the light emitting device 600 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 600 according to this embodiment may be used. In this case, the constituent materials of the electrodes and the like of the light emitting device 600 are formed by transparent members.

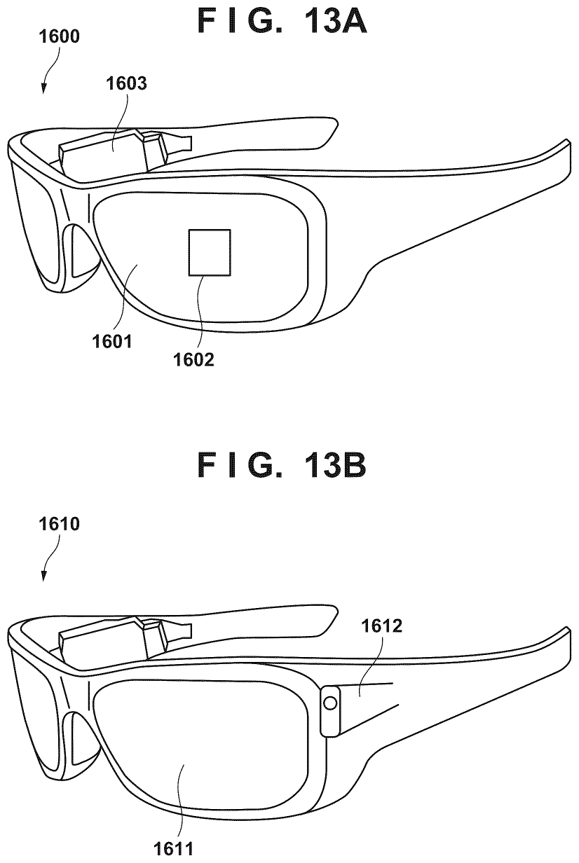

Further application examples of the light emitting device 600 according to this embodiment will be described with reference to FIGS. 13A and 13B. The light emitting device 600 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 13A. An image capturing device 1602 such as a CMOS sensor or an SPAD is provided on the surface side of a lens 1601 of the glasses 1600. In addition, the light emitting device 600 according to this embodiment is provided on the back surface side of the lens 1601.

The glasses 1600 further include a control device 1603. The control device 1603 functions as a power supply that supplies electric power to the image capturing device 1602 and the light emitting device 600 according to each embodiment. In addition, the control device 1603 controls the operations of the image capturing device 1602 and the light emitting device 600. An optical system configured to condense light to the image capturing device 1602 is formed on the lens 1601.

Glasses 1610 (smartglasses) according to one application example will be described with reference to FIG. 13B. The glasses 1610 include a control device 1612, and an image capturing device corresponding to the image capturing device 1602 and the light emitting device 600 are mounted on the control device 1612. The image capturing device in the control device 1612 and an optical system configured to project light emitted from the light emitting device 600 are formed in a lens 1611, and an image is projected to the lens 1611. The control device 1612 functions as a power supply that supplies electric power to the image capturing device and the light emitting device 600, and controls the operations of the image capturing device and the light emitting device 600. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 600 according to the embodiment of the present disclosure can include an image capturing device including a light receiving element, and control a displayed image based on the line-of-sight information of the user from the image capturing device.

More specifically, the light emitting device 600 decides a first visual field region at which the user is gazing and a second visual field region other than the first visual field region based on the line-of-sight information. The first visual field region and the second visual field region may be decided by the control device of the light emitting device 600, or those decided by an external control device may be received. In the display region of the light emitting device 600, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 600, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 600, the image capturing device, or an external device. If the external device holds the AI program, it is transmitted to the light emitting device 600 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-006211, filed Jan. 18, 2024, which is hereby incorporated by reference herein in its entirety.

What is claimed is:

1. A light emitting device comprising a display substrate having a main surface that includes a display region where a display element is arranged and a peripheral region where an infrared ray emitting element and an infrared ray receiving element are arranged, and a light-transmissive substrate arranged to cover the main surface, wherein
in an orthogonal projection to the main surface, the light-transmissive substrate includes a first region that overlaps the display region and a second region that overlaps the peripheral region, and
in each of overlap regions in the second region that overlap the infrared ray emitting element and the infrared ray receiving element in the orthogonal projection to the main surface, a concave portion thinner than the first region or an opening portion is provided.

2. The device according to claim 1, further comprising an adhesive member configured to adhere the display substrate and the light-transmissive substrate,
wherein in the orthogonal projection to the main surface, the adhesive member does not overlap the infrared ray emitting element and the infrared ray receiving element.

3. The device according to claim 2, wherein in the orthogonal projection to the main surface, the infrared ray emitting element and the infrared ray receiving element are arranged between the display element and the adhesive member.

4. The device according to claim 1, wherein
an optical film is arranged on at least one main surface of two main surfaces of the light-transmissive substrate,
if the concave portion is provided, the optical film does not cover the concave portion, and
if the opening portion is provided, the optical film does not cover the opening portion.

5. The device according to claim 1, wherein
in the orthogonal projection to the main surface,
if the concave portion is provided in, among the overlap regions, an overlap region overlapping the infrared ray emitting element, the concave portion is larger than the infrared ray emitting element,
if the concave portion is provided in, among the overlap regions, an overlap region overlapping the infrared ray receiving element, the concave portion is larger than the infrared ray receiving element,
if the opening portion is provided in, among the overlap regions, an overlap region overlapping the infrared ray emitting element, the opening portion is larger than the infrared ray emitting element, and
if the opening portion is provided in, among the overlap regions, an overlap region overlapping the infrared ray receiving element, the opening portion is larger than the infrared ray receiving element.

6. The device according to claim 1, wherein
the concave portion is provided in the overlap region, and
a thickness of the concave portion is not more than half a thickness of the first region.

7. The device according to claim 6, wherein the thickness of the concave portion is not less than 0.1 mm.

8. The device according to claim 1, wherein
the opening portion is provided in the overlap region, and
in the orthogonal projection to the main surface, a resin member is arranged between the opening portion and the display element and between the display substrate and the light-transmissive substrate.

9. The device according to claim 8, wherein in the orthogonal projection to the main surface, the resin member does not overlap the infrared ray emitting element and the infrared ray receiving element.

10. The device according to claim 8, wherein an infrared ray reflective layer is arranged on, of surfaces of the resin member, at least a surface facing the opening portion in the orthogonal projection to the main surface.

11. The device according to claim 10, wherein the infrared ray reflective layer is a metal layer or a layer containing aluminum oxide.

12. The device according to claim 8, wherein the resin member contains a resin added with particles of aluminum oxide.

13. The device according to claim 8, wherein a gap is provided between the resin member and the light-transmissive substrate.

14. A light emitting device comprising a display substrate having a main surface that includes a display region where a display element is arranged and a peripheral region where an infrared ray emitting element and an infrared ray receiving element are arranged, and a light-transmissive substrate arranged to cover the main surface, wherein
in an orthogonal projection to the main surface, the light-transmissive substrate covers the display region and does not cover a region of the peripheral region where the infrared ray emitting element and the infrared ray receiving element are arranged.

15. The device according to claim 14, wherein in the orthogonal projection to the main surface, an outer edge of the light-transmissive substrate is arranged between the display region and the infrared ray emitting element and between the display region and the infrared ray receiving element.

16. The device according to claim 14, further comprising an adhesive member configured to adhere the display substrate and the light-transmissive substrate,
wherein in the orthogonal projection to the main surface, the adhesive member is arranged between the display region and the infrared ray emitting element and between the display region and the infrared ray receiving element.

17. The device according to claim 16, wherein an infrared ray reflective layer is arranged on side surface located in an outer edge of at least one of the light-transmissive substrate and the adhesive member.

18. A display device comprising the light emitting device according to claim 1, and an active element connected to the light emitting device.

19. A photoelectric conversion device comprising an optical unit including a plurality of lenses, an image sensor configured to receive light having passed through the optical unit, and a display unit configured to display an image,
wherein the display unit displays an image captured by the image sensor, and includes the light emitting device according to claim 1.

20. An electronic apparatus comprising a housing provided with a display unit, and a communication unit provided in the housing and configured to perform external communication,
wherein the display unit includes the light emitting device according to claim 1.

21. A wearable device comprising a display device configured to display an image,
wherein the display device includes the light emitting device according to claim 1.
